(19) United States
(12) Patent Application Publication
(10) Pub. No.: US 2006/0212273 A1
(43) Pub. Date: Sep. 21, 2006

(54) Real-time snoring assessment apparatus and method

(75) Inventors: David T. Krausman, Bel Air, MD (US); Roberta M. Allen, Arnold, MD (US)

Correspondence Address: LARRY J. GUFFEY, WORLD TRADE CENER - SUITE 1800, 401 EAST PRATT STREET, BALTIMORE, MD, 21202, US

(73) Assignee: INDIVIDUAL MONITORING SYSTEMS.INC., Baltimore, MD (US)

(21) Appl. No.: 11/073,148

(22) Filed: Mar. 4, 2005

(51) Int. Cl. G06F 15/00; H03F 1/26

(52) U.S. Cl. 702/189

(57) ABSTRACT

A method and apparatus are disclosed for monitoring and assessing the occurrences of a person's snoring activity. Being small and portable, the apparatus is easily attached to a subject and detects and quantifies the subject's snoring behavior. It automatically provides an immediate display of the average number of snores per hour (i.e., a “snore index”) and an indication of the sound intensity of these snores, which are measures of the subject's snoring activity. In a preferred embodiment, this apparatus includes: (a) a sensor to capture the temporal variation of a subject's snoring activity, (b) an analog to digital converter to sample and digitize the captured data, (c) a microprocessor to process the digital data and control the apparatus' operation, (d) a memory device for data storage, (e) a display means, and (f) an embedded firmware program that controls the: (i) sampling and storage of the data, (ii) analysis of the data to compute the average number of snores per hour and their intensity, and (iii) the operation of the display means and the possible downloading of the data.

### BACKGROUND OF THE INVENTION

1. Field of the Invention

This invention relates to physiological monitoring and diagnostic testing devices and methods. More particularly, this invention relates to a device and method for monitoring and assessing the occurrences of a person's snoring activity during sleep.

2. Description of the Related Art

Some forty five percent of normal adults snore at least occasionally, and twenty five percent are habitual snorers. Problem snoring is more frequent in males and overweight persons, and it usually grows worse with age. Snoring is a common sleeping disorder, which affects at least thirty percent of the adult population. A published report by Young et al. (New England Journal of Medicine. 1993; 328:1230-1235) was conducted through a self-report questionnaire to 3,513 respondents that showed 28% of women and 44% of men between the ages of 30 and 60 were habitual snorers.

Most epidemiologic data on snoring comes from self-reporting, which is potentially limited. Thus, the need exists for an easy, accurate and objective method and device for assessing snoring—especially when attempting to document the efficacy of a new procedure for the treatment of snoring where subjective data is not adequate. Since so many snorers suffer from sleep apnea, such a device could also serve as a diagnostic or screening tool for identifying those suspected of having sleep apnea or other forms of respiratory related sleep disorders.

Although there remains no standardization of the spectral characteristics of snoring sounds, it appears that the low frequency, respiratory, snoring noises differ due to the occurrence of various structural sources within the upper airway. The frequency content of snoring caused by the palate and uvula will usually differ from 1s the frequency content of snoring caused by sites lower in the throat.

Another variable that will produce different frequency ranges of the snoring sound are attributed to the type of transducer or sensor used to capture the snoring sounds. Acoustic microphones generally will produce both fundamental and complex harmonic snoring vibrations in the 20-300 Hertz range, while facial surface mounted transducers and air pressure sensors typically do not respond to the higher acoustical harmonics but capture fundamental vibratory frequencies in the 30-70 Hertz range.

More than 300 devices are registered in the U.S. Patent and Trademark Office as cures for snoring. These include: assorted variations on the old idea of sewing a tennis ball on one's pajama back to force the snorer to sleep on his side (as snoring is often worse when the person sleeps on his or her back), chin and head straps, neck collars, assorted electrical devices that are designed to produce painful or unpleasant stimuli when one snores (e.g., the commercially available, anti-snoring device “ANTISNORE” by Ambulatory Monitoring, Ardsley, N.Y.). Most of these devices presume that a person can be trained or conditioned not to snore. Unfortunately, snoring is not under the person's control; thus, if any of these devices work, it is most likely because they keep the snorer awake.

During sleep, snoring occurs when air flows past relaxed tissues in the throat, causing the tissues to vibrate as one breathes to generate hoarse or harsh sounds. Snoring sounds can occur during both the inspiration and expiration breathing cycle, but are typically most prominent during inspiration.

As one dozes off to sleep and progresses from a lighter sleep to a deeper sleep, the muscles in the roof of one's mouth (soft palate), tongue and throat relax. When these tissues relax enough, they can vibrate and partially obstruct one's airway which at equivalent volume flow rates requires higher airflow velocities which can increase the amplitude of tissue vibrations and yield louder snoring sounds.

Having a low, thick soft palate or enlarged tonsils or tissues in the back of the throat (adenoids) can also narrow the airway. Likewise, if the triangular piece of tissue hanging from the soft palate (uvula) is elongated, airflow can be obstructed and vibration increased. Being overweight can also contribute to narrowing of one's throat tissues.

Snoring can also be brought on by consuming excessive alcohol before bedtime. Alcohol acts like a sedative, relaxing throat muscles. Chronic nasal congestion such as allergies or a crooked partition between the nostrils (deviated nasal septum) may also limit airflow through the nose. This forces breathing through the mouth, increasing the likelihood of snoring.

Snoring may also be associated with sleep apnea. The most exaggerated form of snoring is known as obstructive sleep apnea, when loud snoring is interrupted by frequent episodes of obstructed breathing. This is a serious condition where excessive sagging of throat tissues causes the airway to collapse, preventing or restricting breathing during sleep. Apnea generally breaks up loud snoring with ten seconds or more of silence. Eventually, the lack of oxygen and an increase in carbon dioxide signals such a patient to wake up, usually with a loud snort as one's airway is opened.

Habitual snoring may be more than just a nuisance and a cause of daytime sleepiness. Untreated, persistent snoring may raise one's lifetime risk of developing such health problems as diabetes, high blood pressure and even heart failure and stroke. In children, snoring may increase their risk of attention-deficit/hyperactivity disorder (ADHD).

Snoring also has social consequences. It is disruptive to family life and can make the snorer an object of ridicule and can cause other household members sleepless nights, thereby possibly building resentment towards a snorer.

Traditional snore sensing and monitoring has been accomplished through the use of various transducer devices, such as piezo-ceramic elements, polyvinylidene fluoride film (PVDF) and acoustic and vibratory microphones. These sensors are typically placed at various locations about the face and neck to include: on the neck, on the nose, under the nostrils, over the mouth or in proximity to the oral/nasal cavity.

It has been observed that although all of these locations can physically vibrate during snoring activity, placement of the sensor can be critical for accurately monitoring the quality and relative amplitude of these vibrations. Displacement of the sensor during sleep is also a problem that can affect the integrity and accuracy of the recorded signal, especially for unattended monitoring. For most current testing methods, these transducer sensors are typically tethered to a bedside monitoring console or to a data logger where post sleep snore data is downloaded to a host computer for analysis.

In the prior art, various sensors for snore detection have been integrated into a variety of computerized data logging systems in which the dynamic characteristics of respiratory sounds, and in particular the snoring component of the respiratory signal, have been recorded for post sleep analysis. These applications typically use vibratory detection methods and post analysis techniques (e.g., U.S. Pat. No. 5,879,313) to analyze and classify snoring sounds so as to identify types and sources of sleep disorders (e.g., sleep apnea).

This technology is presently used in a commercial sleep apnea and snoring monitor (SNAP Laboratories, Wheeling, Ill.) which provides in home monitoring; with the device being returned to the lab for data download and analysis which allows for a report to be provided to the referring physician. U.S. Pat. No. 4,982,738 similarly utilizes a microphone system to capture and store signals that are indicative of snoring sounds; with the time intervals between snoring episodes being computed by complex post-sleep analysis means so as to calculate a respiration disturbance index. One such commercial product utilizing this microphone snore measurement methodology is the “SnoreSat” (SagaTech Electronics, Calgary, AB).

U.S. Patent Application No. 2003/0066529 (Truschel, W. et al., 2003) discloses a method and apparatus for detecting patient snoring activity and dynamically determining a snore detection threshold for automatic adjustment and control of air pressure delivery which is provided to a patient where such control can be incorporated into a continuous positive air pressure (CPAP) apparatus commonly used to treat sleep apnea patients.

Other prior art efforts to provide a means of assessing snoring behaviors have included the use of acoustic screening of respiration by a behavior modification device that detects loud snoring, or an alarm device that wakes the patient when a period of silence occurs that indicates a dangerously long acute sleep apnea episode (see U.S. Pat. Nos. 4,715,367, 4,306,567 and 4,129,125).

U.S. Pat. No. 4,982,738 discloses the inclusion of sensors for recording the time intervals between snoring events. Such advances have improved the content of the data recorded for later analysis by trained personnel.

U.S. Pat. No. 5,275,159 discloses the use of a computer in conjunction with a data logger to improve the presentation of recorded data. The data logged is shown to be presentable under any of three possible formats: (1) as a graph of sensor value versus time; (2) as histograms and tables; and (3) as episodes per hour of a selected parameter.

An alternative method for measuring snoring has been disclosed to be a standardized, self-test “SNORE SCORE” quiz that is used by sleep specialists and the sleep disorder community. This quiz is designed to help those who are already aware that they snore and is used to determine whether or not their snoring is just an irritation to a sleep partner, or a symptom of a more serious condition such as sleep apnea. Another similar, patient-derived, snoring questionnaire useful for clinical snoring assessment is the “SNORING SYMPTOMS INVENTORY” that was published in “Clinical Otolaryngology,” 2003; vol. 28, pp. 18-21.

Besides the use of dedicated apparatus and self-test questioners to assess snoring behaviors, many patients are routinely directed to sleep disorder centers that are designed to assess snoring objectively and determine whether it is a symptom of sleep apnea. In a clinical study reported by Hoffstein et al. (“Sleep,” September 1994, vol. 17, p. 6), 613 patients were referred to a sleep laboratory for an assessment of their sleep and snoring patterns. All the patients had standard nocturnal polysomnography (PSG) to determine various sleep parameters; this study also included measurements of snoring by the use of a sound level meter and microphone. Resulting data for snoring assessment was expressed as the number of snores per hour of sleep expressed as the snoring index (SI) and both the mean dB and maximum dB sound intensities were measured. The results of these studies concluded that self-perception of snoring by the listener is inaccurate and that an objective measurement of a patient's snoring correlates only moderately with the subjective perception by a listener or the patient's bed-partner.

Although the prior art methods have been useful for assessing the presence and frequency of snoring events (either by manually or computer scoring collected snoring data for a specified sleep period), there continues to be a need for new and improved alternative, quantitative means of assessing one's snoring and sleep habits.

3. Objects and Advantages

There has been summarized above, rather broadly, the prior art that is related to the present invention in order that the context of the present invention may be better understood and appreciated. In this regard, it is instructive to also consider the objects and advantages of the present invention.

It is an object of the present invention to provide an easy means for one to assess the frequency and intensity of his/her snoring activity during a specified sleep period.

It is also an object of the present invention to provide an apparatus to real-time detect and document the occurrences of one's snoring activity during a specified sleep period.

It is an object of the present invention to provide an apparatus that automatically computes the frequency and intensity of snoring activity during a specified sleep period.

It is another object of the present invention to provide a device that is reasonably accurate, compact, and easy to use, and that provides immediate visual feedback scores of one's nightly snoring activity.

It is also an object of the present invention to provide immediate feedback in the form of a numeric display indicating the final snore scores for a specified sleep period.

It is an object of this present invention to use the measurement and computation of snoring activity as a means to calculate and display a scoring index in the form of an index (e.g., snores per hour) that is representative of a user's snoring behaviors during a specified sleep period.

It is an additional object of this present invention to use the measurement and computation of snoring activity as a means to calculate and display the average intensity that is representative of a user's snoring behavior during a specified sleep period.

It is an object of this present invention to use the measurement and computation of snoring activity as a means to calculate and display the peak intensity representative of a user's snoring behavior during a specified sleep period.

It is also an object of the present invention to provide a method for the storage and download of snoring data collected over a specified sleep period so that this data can be further analyzed by an external computer.

It is yet another object of the present invention to provide a snore assessment device that can be used without the direct guidance of a sleep professional.

These and other objects and advantages of the present invention will become readily apparent as the invention is better understood by reference to the accompanying summary, drawings and the detailed description that follows.

### SUMMARY OF THE INVENTION

Recognizing the need for a much simpler apparatus and method for assessing one's snoring habits, the present invention is generally directed to satisfying the needs set forth above and the problems identified with prior systems for assessing one's snoring patterns.

In accordance with one preferred embodiment of the present invention, the foregoing need can be satisfied by providing a snore meter or snore scoring apparatus which includes: (1) an oral/nasal air cannula sensor tube to capture the respiratory airflow that quantifies the temporal variation of a subject's snoring activity, (2) an air pressure transducer to convert the sensed air pressure into an electrical analog form, (3) a signal filtering and conditioning circuit to extract the higher frequency snoring signal from the lower frequency breathing signal, (4) an analog to digital converter to sample and digitize the snore signal into digital form, (5) a microprocessor with embedded programmable firmware memory to store and process the digital data and control the apparatus' operation, (6) a memory device for data storage, (7) a display means, (8) a switch for resetting the device and controlling the displays means, and (9) an embedded firmware program that controls: (i) the sampling of the snore signal at prescribed time intervals and the subsequent storage of this data in the memory device, (ii) the analysis of the snore data to compute a “snore index” which is a measure of the subject's snoring activity, and (iii) the operation of the display means and the possible downloading of the data.

Because of its miniaturized size, this apparatus can be strapped about the chest or easily clipped to one's bedclothes or slipped under the pillow while sleeping. The device, with its attached cannula, samples and quantifies one's snoring vibrations to determine a snore score based on parameters such as the: frequency of snoring events per hour (snore index), average amplitude of snoring events, peak amplitude of snoring events, total time of snoring activity and the length of one's sleep period.

This sleep period or sleep time can be easily set by an apparatus user by a push-button switch on the apparatus that is pushed to start and stop the monitored sleep period. Upon termination of this sleep period, the apparatus' display means can display the calculated values of one snore scores. Each scored variable can be saved in memory for recall by utilizing the push-button on the display means. Both saved scores and raw data are available for download for further analysis by an external computer.

Thus, there has been summarized above, rather broadly, the more important features of the present invention in order that the detailed description that follows may be better understood and appreciated. There are, of course, additional features of the invention that will be described hereinafter and which will form the subject matter of any eventual claims to this invention.

In this respect, before explaining at least one embodiment of the present invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting.

### BRIEF DESCRIPTION OF THE DRAWINGS

FIG. 1 illustrates the approximate placement of a cannula connected to a preferred embodiment of the present invention.

FIG. 2 is a schematic flow diagram of a preferred embodiment of the present invention.

FIG. 3 shows an oscilloscope tracing of the airflow pressure signal comprising the breathing and snoring signals collected by the preferred embodiment shown in FIG. 2, wherein it can be noted that the low frequency signal waveform is the monitored inspiration and expiration breathing component and the high frequency snoring signal is seen to be superimposed at the peak of the inspiration wave.

FIG. 4 illustrates an oscilloscope tracing of a snoring tracing at about 48 Hz that has been extracted from the breathing signal utilizing a high pass, 120 Hz filter.

FIGS. 5a and 5b together provide a schematic circuit diagram for a preferred embodiment of the present invention.

### DESCRIPTION OF THE PREFERRED EMBODIMENT

The present invention is based on related real-time detection, assessment and immediate report methods previously described by the one of the present inventors in U.S. Pat. No. 6,142,950, which is entitled “Non-Tethered Apnea Screening Device.” Among other things, this patent discloses a monitoring device for evaluating a fully ambulatory subject so as to provide an immediate numeric display, on the device itself and without the need to download any data, of the sleep apnea events experienced by the subject in a specified time period. The present invention uses similar technology to yield a report of a user's snoring activity during a prescribed period.

In another U.S. patent, which is soon to be granted to one of the present inventors' based on U.S. patent application Ser. No. 10/287,253: “Sleep Scoring Apparatus and Method,” a similar real-time detection and assessment methodology was used. These inventors used such techniques to provide a physiological monitoring and diagnostic tool that computes and immediately yields, without data downloading, a person's “Sleep Score” based on a wearer's limb movements.

The assessment and computation of real-time, “on-the-fly” physiological events that is described in these two cited works of one of the present inventors serves as the groundwork for the development of the present invention.

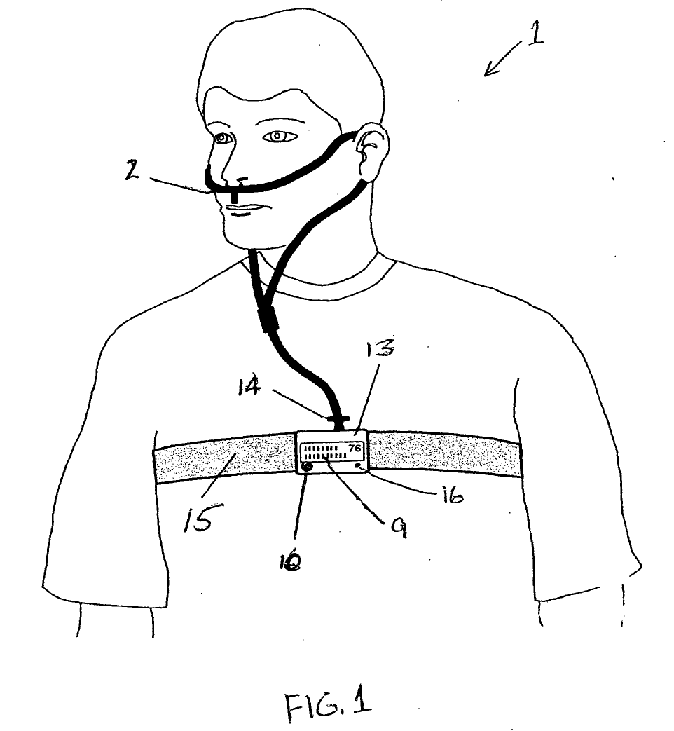

In accordance with one preferred embodiment of the present invention, a method for evaluating a fully ambulatory subject for snoring activity includes the steps of: (1) locating on the subject's upper lip, a combined oral and nasal airflow pressure cannula tube to capture a subject's respiratory airflow for a prescribed time period, see FIG. 1 for such an arrangement, (2) inputting this captured signal to an air pressure transducer which yield an electrical signal that is representative of the subject's respiratory breathing, (3) using suitable signal filtering methods to extract from this captured respiratory airflow signal the superimposed higher frequency signal attributable to the subject's snoring patterns, (4) converting this captured signal from analog to digital form, (5) storing this digital signal in the memory device of a microprocessor, (6) providing this microprocessor with firmware that controls the sampling and analysis of this stored signal, (7) analyzing this captured signal to compute a snore score or index that is indicative of the subject's snoring during the prescribed, monitored time period, and (8) displaying this snore index on a display means attached to the microprocessor.

In accordance with another preferred embodiment of the present invention, a snore meter or snore scoring apparatus or device 1 includes: an oral/nasal air cannula sensor tube 2 to capture the respiratory airflow that quantifies the temporal variation of the subject's snoring activity at the sensor's location, an air pressure transducer 3 to receive the subject's respiratory air flow from the sensing tube 2 and convert its driving air pressure into an electrical analog form, a signal filtering and conditioning circuit 4 to extract the higher frequency snoring signal from the lower frequency breathing signal, an analog to digital converter 5 to sample and digitize the snore signal into digital form, a microprocessor 6 with embedded programmable firmware memory 7 to store and process the digital data and control its functional operation, a memory device 8 for data storage, a display means 9 such as an LCD readout, a switch 10 for resetting the apparatus 1 and controlling the displays means 9, and an embedded firmware program 11 that directs the microprocessor 6 to: (i) sample the snore signal at prescribed time intervals and to store this data in the memory device 7, (ii) analyze the snore data to compute a snore score based on the frequency and magnitude of the snoring signal recorded during the monitoring period, (iii) compute the total time of snoring activity and the length of the sleep period, and (iv) control the operation of the display means 9, and a data download driver 12 that allows the stored data to be downloaded for more complex analysis of the data by an external computer.

This device's air pressure sensor has the advantage over other transducing devices (e.g., microphone or piezo film elements) typically used for snoring detection because its signal quality remains quite stable even if the nasal/oral cannula is slightly displaced or moves during sleep. In contrast, other sensors have measurement artifacts resulting from body movements or displacement of their snore-sensing element.

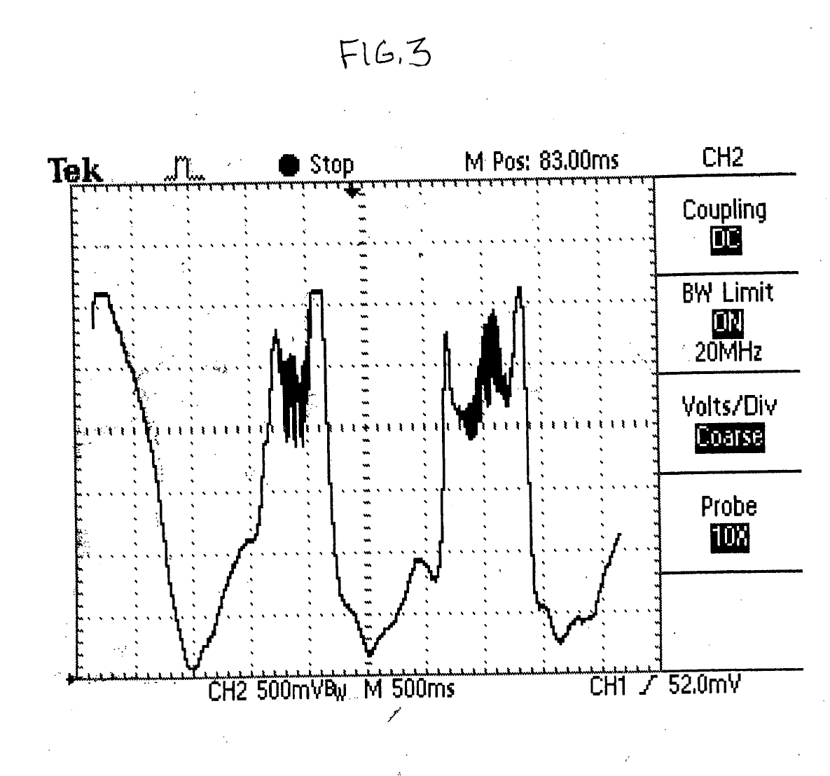

The distal end of the oral/nasal cannula is connected to a pressure transducer 3 contained in the monitoring unit 13. This combination detects the pressure fluctuations caused by inspiration and expiration where the signal's contour is basically proportional to airflow, see FIG. 3.

The combined oral and nasal airflow pressure cannula 2, which is similar to an oxygen delivery tube, can, because of its lanyard style, be easily applied to a subject's upper lip by routing the sensing cannula tube behind the ears and tightening a draw-slide to provide secure attachment. The distal end of the cannula, with integral bacteria filter 14, is then connected to the snore monitor unit 13 via a standard lour-lock fitting. Two of the cannula's prongs (air intake ports) are placed into the nares and a third port captures the respiratory airflow pressure at the mouth.

While the cannula prongs rest comfortably in the nares, the third integrated cannula port containing an air-accumulator, positioned in front of the mouth, captures the oral airflow; FIG. 3 for an example of the type of signal received. Using the nasal placement serves to stabilize positional integrity of the cannula with little or no physical displacement while making the facial apparatus more user friendly, practical and unobtrusive for unattended at-home recording. The disposable air-hose cannulas are inexpensive and require no cleaning since they are designed for single use only. Such cannulas are readily commercially available (e.g., from Pro-Tech FDA No. K982293, model 1294; Braebon FDA No. K984431, model 0589/0588).

An integral in-line disposable filter 14 (part of the air cannula assembly) ensures that any bacteria or contaminating materials will be captured in the filter and not allowed to reach the pressure transducer contained in the monitor 13.

The snore monitor 13 is attached to an adjustable belt 15 which is worn about the upper chest to reduce problems associated with lying on the unit during sleep. Additionally, this location has been shown to markedly reduce the chance of entanglement or dislodging of the cannula hose. However, the belt 15 can be removed and the monitor 13 can alternately be placed in a sleeping-shirt pocket, clipped to bedclothes or simply placed under the pillow.

The cannula 2 with filter 14 is accordingly attached to the snore monitor 13 via a standard Lour-lock connector with the cannula providing direct input of air flow pressure to a solid-state pressure transducer 3 (Silicon Microstructures, Inc. Model No. SM5350). This transducer 3 is very small and ideally suited for this application (with a range of 0.0-6.3 cm. H₂O [0.0-0.9 psi] and a linearity of ±0.1% full scale). These pressure scales fit well within the required range to fully encompass human breathing which typically ranges from 0.5 to 2.0 cm H₂O for quiet breathing with maximums to 6.0 cm H₂O with increased inspiration and snore driving pressure.

A recording session with the present invention is initiated by pressing a front panel or reset button 10 for from five to fifteen seconds. This will store the current readings and reset the display to zero and begin the collection of the pressure data related to a user's snoring activity. The monitored sleep period can range from minutes to many hours.

The accumulated on-going snore score results are continually updated in real-time (on-the-fly) and displayed on the display means 9 or LCD readout located on the front panel of the unit 13. When the user awakens, a momentary press of the panel button 10 will terminate of the recording session and provide the final computation of the snore scoring results on the LCD readout 9.

The embedded firmware program 11 controls the analysis of the collected data. The results of this analysis yield several parameters that can be readily displayed on the LCD readout 9. These include: (i) a snoring index or index of snoring, which can be defined in many readily apparent ways by those familiar with snoring data (e.g., snoring index=the average number of snores per some portion (i.e., an hour) of one's monitored sleep period, (ii) a measure of snoring activity, which can be defined as the average magnitude of the monitored snoring pressures, (iii) the peak magnitude of the snoring pressures observed for specified portions of the monitored sleep period, (iv) the total time during snoring activity was observed to occur, and (v) the length of the monitored sleep period.

Additionally, both the computed and the raw data from a recording session are available for download and further analysis by an external computer. The firmware program 11 for the microprocessor 6 is such that it also provides the ability by a short push on the reset button 10 to retrieve and display snore scores from previous sleep periods. The firmware program 11 also provides the ability to allow a user to clear all data (both current and memory) by pressing the panel push button 10 for a specified duration (e.g., 15 seconds or longer).

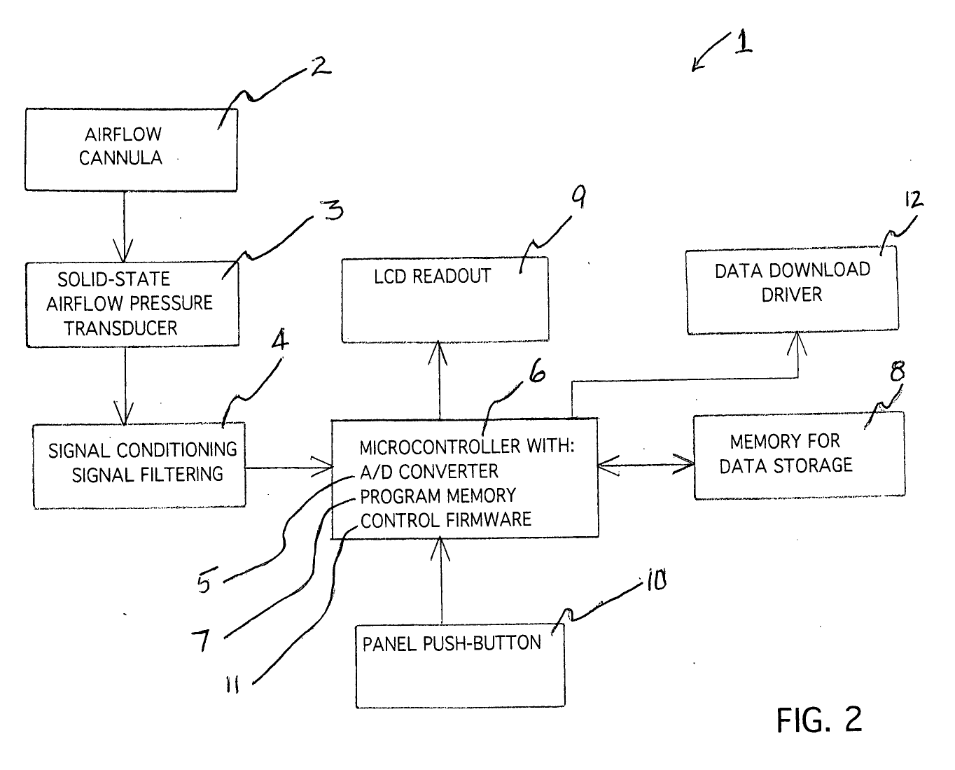

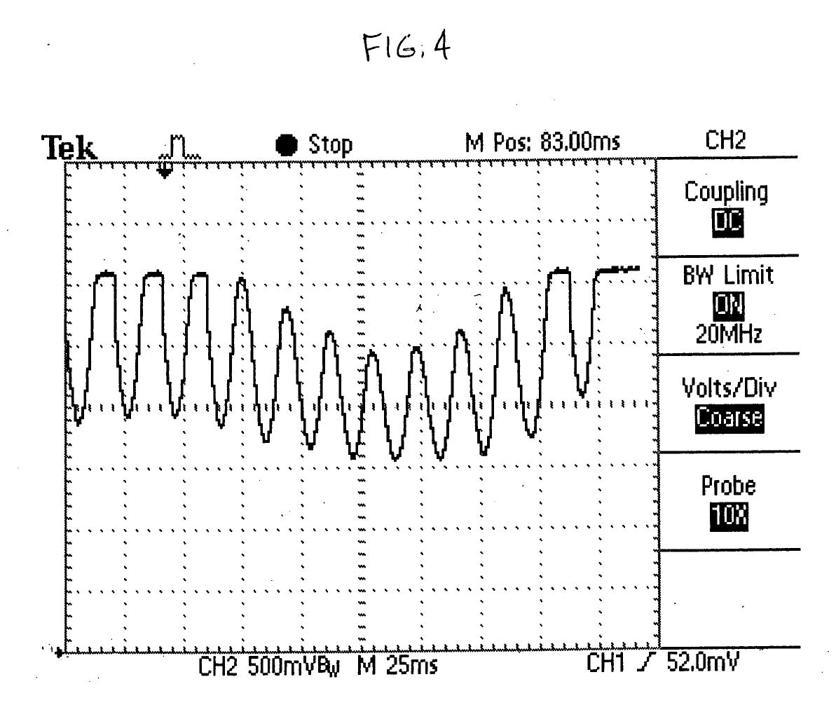

A schematic block diagram of this battery-operated, ambulatory device 1 is shown in FIG. 2. These blocks serve to further describe the functional operation of the various components of the device: (a) a three port, airflow pressure cannula tube or hose 2 connected to an solid-state, airflow pressure transducer 3 with appropriate signal conditioning and filtering circuitry 4 extracts the snoring component from the breathing signal using a Butterworth filter to yield required levels of signal fidelity, thus providing an output signal that quantifies the temporal variations of the amplitude and frequency of subject's snoring activity, (b) an analog to digital converter 5 integral to the microprocessor 6 samples snoring data at a sampling frequency of 200 Hz which is sufficient to encompass the fundamental frequency range of snoring activity (typically ranging from 30-70 Hz when measured by a cannula based airflow pressure means, see FIG. 4), (c) the microprocessor 6 with embedded programmable memory 7 controls the processing firmware 11, which includes appropriate algorithms to compute snore scores based on airflow pressure data provided by the airflow pressure transducer 3, (d) a memory device 8 stores the computed real-time and raw snore data, (e) a push button 10 helps to control the device, (f) an LCD readout 9 displays various computed snoring results, including an index of snoring (average number of snores per hour), the average magnitude of the snoring pressures, ii) the peak magnitude of the snoring pressures, the total snoring time, and the duration of the sleep period, and (g) a serial output port 16 provides a means to download data for further analysis by an external computer.

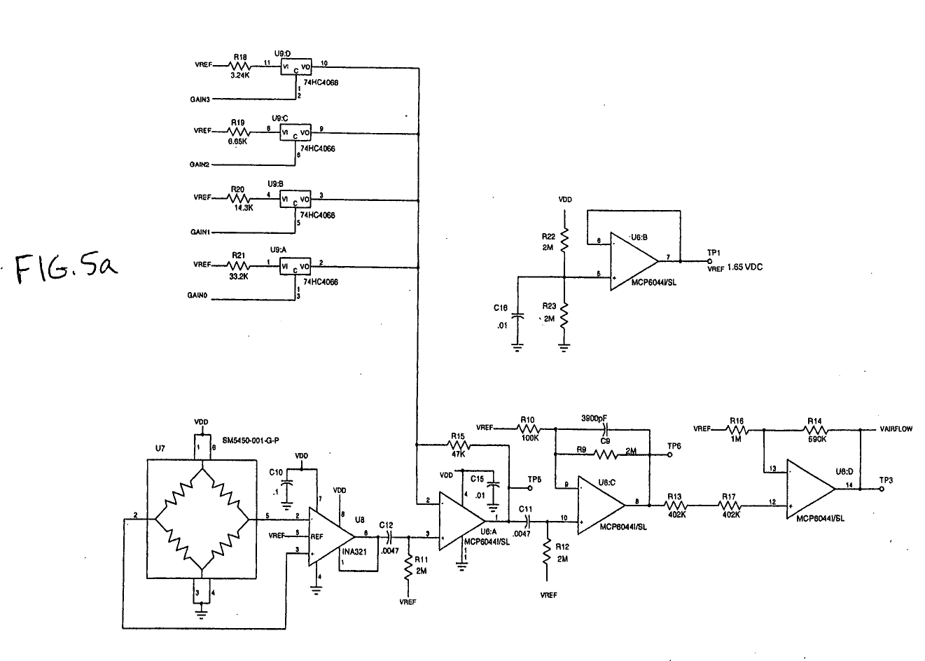

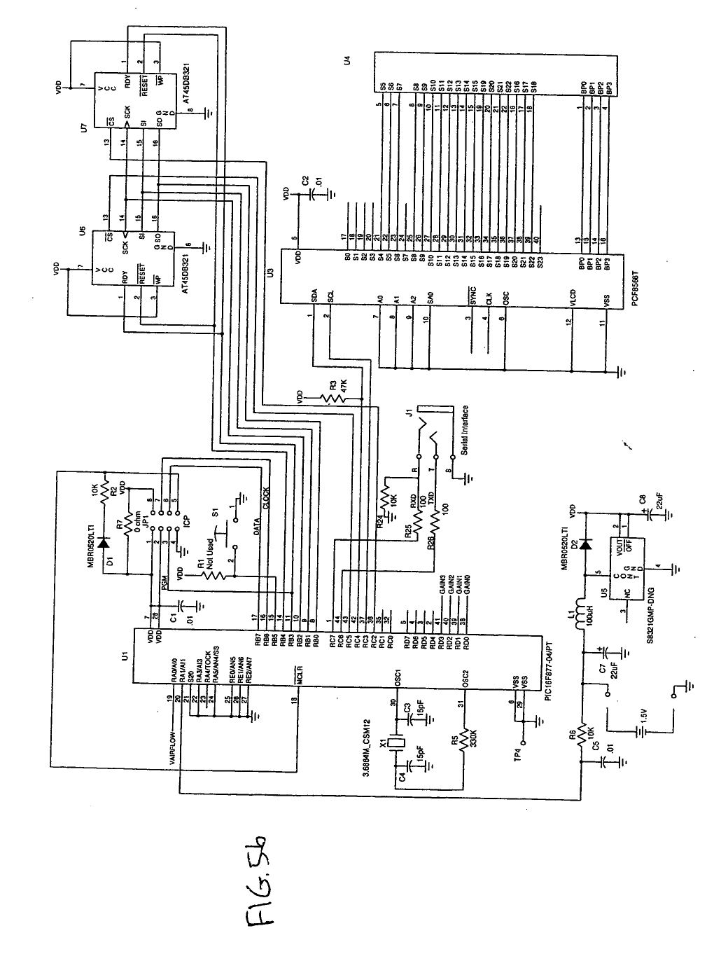

Specific components used in a preferred embodiment of the present invention include: (1) an ultra-low power CMOS Microchip PIC 16F877A microprocessor with programmable nonvolatile FLASH memory, the microprocessor containing: (i) 4K programmable memory for the firmware, (ii) an integral analog to digital converter for sampling and digitizing the snoring signal waveform, (iii) an integral, full-duplex serial communications port for compatibility with the download technology to communicate with an external computer, (iv) control and input/output lines to interface and communicate with circuit board chips, LCD display and other circuit components, and (iv) programmed firmware written in Assembly Language for the PIC processor. A suitable schematic circuit diagram for use with such components is shown in FIGS. 5a and 5b.

For this preferred embodiment, internal, read-only program software provided: (i) firmware for detecting a threshold level above a prescribed baseline and for storing the snoring data at a sampling rate of 200 Hertz, (ii) firmware to detect the presence and magnitude snoring activity and to time stamp the beginning and end of a detected snoring burst during each breath, (iii) firmware to disregard data below an established baseline and to store only the digitized snoring data to preserve memory space, (iv) firmware for converting the digitized airflow pressure signals from cm. H₂O to other prescribed units of measure such as a reference scale (e.g. 0-100) or to dB units for ease of comprehension, (v) firmware is to compute and display the snore index of snores per hour, (vi) firmware to compute and display the average snore pressure level in prescribed units of measure, (vii) firmware to compute and display peak snore pressure level in prescribed units of measure, (viii) firmware to calculate and display total time in snoring activity, and (ix) firmware to compute and display the length of the sleep period.

The printed circuit board for this preferred embodiment utilized a 4-layer design containing both through hole and SMT pads for circuit and chip components, which included: (i) Silicon Microstructures, Inc. pressure transducer Model No. SM5350, (ii) a 10 bit analog to digital converter located within the microprocessor chip, (iii) data memory comprised of non-volatile FLASH memory chips, Atmel No. AT45DB321 or equivalent, (iv) a custom LCD display, and (v) a replaceable AA alkaline battery allowing for about 100 hours of operation.

Since the present invention may also provide storage and recall functions (where snore results from previous sleep periods can be sequentially display by means of a push button), it can allow for automatic night-to-night data storage which enables one to track night-to-night snoring in either a clinical environment or in the home setting.

In other embodiments of the present invention, the combination of the present airflow pressure cannula 2 and snore sensing transducer 3 can be replaced by alternate data capture and transducer means for detecting snoring activity so as to produce analog waveforms of the snoring signal for input to the present invention. For example, with minor adjustments to the circuit schematic and firmware program, the present invention can be configured to accept the following types of snore sensors: (1) a piezo-ceramic element (manufactured by Pro-Tech, Mukiteo, Wash. and by Sleepmate, Midlothian, Va. and others), (2) a snore microphone (manufactured by Pro-Tech and Sleepmate, among others) or various other types of vibratory and acoustical microphones, (3) a polyvinylidene fluoride film (PVDF) manufactured by Dymedix Corp., which is flexible and uses an adhesive backing for attachment.

These and other forms of sensors are placed at respective locations that respond most favorably to snore vibrations (e.g., the neck, on the nose, under the nostrils, over the mouth or in proximity to the oral/nasal cavity). It has been observed that although all of these locations physically vibrate during snoring activity, placement of the sensor is critical for maintaining good quality and relative amplitude of the vibrating snore signal and each type of alternate sensor requires appropriate signal conditioning and filtering circuitry to produce the required characteristics to accurately measure and assess snoring activity.

It is to be understood that the invention is not limited in its application to the details of construction and to the arrangements of the components set forth in the previous description or illustrated in the drawings. The invention is capable of other embodiments and of being practiced and carried out in various ways. For example the snore score monitor may be in the form of a re-useable device or, may take the form of a disposable unit.

Although the foregoing disclosure relates to preferred embodiments of the invention, it is understood that these details have been given for the purposes of clarification only. Various changes and modifications of the invention will be apparent, to one having ordinary skill in the art, without departing from the spirit and scope of the invention as hereinafter set forth in the claims.

We claim:

1. An apparatus for the real-time evaluation of the snoring activity of a subject during a specified sleep period, said apparatus comprising:
a means for capturing the temporal variation in an analog signal that is indicative of the snoring activity of said subject,
a means, connected to said signal capturing means, for the real-time conversion of said analog signal into digital data,
a means, connected to said converting means, for the real-time computer processing of said digital data,
a means, connected to said processing means, for the real-time storing of a specified portion of said digital data,
a means, connected to said processing means, for the real-time displaying of a value that is computed by said processing means operating in real-time and in a prescribed manner on said digital data, and
a means, connected to said processing means, for controlling the operation of said apparatus by directing said processing means to sample the output of said conversion means at a prescribed time interval and to store said sampled data in said storage means, by directing said processing means to analyze in real-time a specified portion of said stored data to compute a value which is a measure of the snore activity of said subject during the time period associated with said specified portion of said stored data, and by directing said display means to display said computed value.

2. The apparatus as recited in claim 1, further comprising:
a means, connected to said signal capturing means, for transducing said captured analog signal into an electrical signal.

3. The apparatus as recited in claim 1, further comprising:
a means, connected to said transducing means, for filtering and conditioning said electrical signal to extract the frequency range associated with the snoring activities of said subject and yield an extracted signal having a specified level of signal fidelity.

4. The apparatus as recited in claim 2, further comprising:
a means, connected to said transducing means, for filtering and conditioning said electrical signal to extract the frequency range associated with the snoring activities of said subject and yield an extracted signal having a specified level of signal fidelity.

5. The apparatus as recited in claim 1, further comprising:
a means, connected to said processing means, for initiating and stopping said capture of said analog signal and causing said display means to display said computed value.

6. The apparatus as recited in claim 4, further comprising:
a means, connected to said processing means, for initiating and stopping said capture of said analog signal and causing said display means to display said computed value.

7. The apparatus as recited in claim 1, further comprising:
a means, connected to said processing means, for downloading said stored data to an external computer.

8. The apparatus as recited in claim 6, further comprising:
a means, connected to said processing means, for downloading said stored data to an external computer.

9. The apparatus as recited in claim 1, wherein said computed value is chosen from the group consisting of a prescribed snore index that is related to the number of snores identified in said captured signal per a prescribed time period, a measure of said snoring activity that is related to the magnitude of said snores identified in said captured signal over a prescribed time period, or the duration of time for which snoring activity is identified to be present during a prescribed time period.

10. The apparatus as recited in claim 8, wherein said computed value is chosen from the group consisting of a prescribed snore index that is related to the number of snores identified in said captured signal per a prescribed time period, a measure of said snoring activity that is related to the magnitude of said snores identified in said captured signal over a prescribed time period, or the duration of time for which snoring activity is identified to be present during a prescribed time period.

11. A method for the real-time evaluation of the snoring activity of a subject during a specified sleep period, said method comprising the steps of:
locating a snore monitoring apparatus at a prescribed location on said subject, said apparatus having a sensor that captures an analog signal that is indicative of the snoring activity of said subject, a converter that converts said signal from analog to digital, a microprocessor having embedded programmable memory, a data storage means, a display means, and firmware that controls the operation of said apparatus and includes algorithms for computing a value which is indicative of the snore activity monitored during a specified portion of said monitored sleep period,
sampling in real-time the output of said converter at a prescribed time interval,
storing in real-time said sampled data in said data storage means,
analyzing in real-time a specifiable portion of said stored data to compute said value which is indicative of the snore activity monitored during a specified portion of said monitored sleep period, and
displaying in real-time on said display means said computed value.

12. The method as recited in claim 11, wherein said apparatus further having a means for transducing said captured analog signal into an electrical signal.

13. The method as recited in claim 11, wherein said apparatus further having a means for filtering and conditioning said electrical signal to extract the frequency range associated with the snoring activities of said subject and yield an extracted signal having a specified level of signal fidelity.

14. The method as recited in claim 12, wherein said apparatus further having a means for filtering and conditioning said electrical signal to extract the frequency range associated with the snoring activities of said subject and yield an extracted signal having a specified level of signal fidelity.

15. The method as recited in claim 11, wherein said apparatus further having a means for initiating and stopping said capture of said analog signal and causing said display means to display said computed value.

16. The method as recited in claim 14, wherein said apparatus further having a means for initiating and stopping said capture of said analog signal and causing said display means to display said computed value.

17. The method as recited in claim 11, wherein said apparatus further having a means for downloading said stored data to an external computer.

18. The method as recited in claim 16, wherein said apparatus further having a means for downloading said stored data to an external computer.

19. The method as recited in claim 11, wherein said computed value is chosen from the group consisting of a prescribed snore index that is related to the number of snores identified in said captured signal per a prescribed time period, a measure of said snoring activity that is related to the magnitude of said snores identified in said captured signal over a prescribed time period, or the duration of time for which snoring activity is identified to be present during a prescribed time period.

20. The method as recited in claim 18, wherein said computed value is chosen from the group consisting of a prescribed snore index that is related to the number of snores identified in said captured signal per a prescribed time period, a measure of said snoring activity that is related to the magnitude of said snores identified in said captured signal over a prescribed time period, or the duration of time for which snoring activity is identified to be present during a prescribed time period.
